(19) United States
(12) Patent Application Publication
(10) Pub. No.: US 2022/0205099 A1
(43) Pub. Date: Jun. 30, 2022

(54) GROUP IV ELEMENT CONTAINING PRECURSORS AND DEPOSITION OF GROUP IV ELEMENT CONTAINING FILMS

(71) Applicant: L'Air Liquide, Société Anonyme pour l'Etude et l'Exploitation des Procédés Georges Claude, Paris (FR)

(72) Inventors: Su-Hyun KIM, Seoul (KR); Wontae NOH, Seoul (KR); Jooho LEE, Seoul (KR)

(21) Appl. No.: 17/136,181

(22) Filed: Dec. 29, 2020

(51) Int. Cl. C23C 16/455; C01G 25/02; C01G 53/00; C01G 51/00; C01B 25/45; H01M 4/36; H01M 4/505; H01M 4/525; H01M 4/58; H01M 4/485; H01M 10/0525; C07F 7/00; C23C 16/40; C23C 16/44; C23C 16/50

(52) U.S. Cl. CPC C23C 16/45553; H01M 2004/028; C01G 53/44; C01G 51/42; C01B 25/45; H01M 4/366; H01M 4/505; H01M 4/525; H01M 4/5825; H01M 4/485; H01M 10/0525; C07F 7/00; C23C 16/405; C23C 16/4408; C23C 16/45555; C23C 16/45534; C23C 16/50; C23C 16/4417; C01P 2004/84; C01P 2006/40; C01G 25/02

(57) ABSTRACT

A method for forming a Group IV transition metal containing film comprises
a) exposing a substrate to a vapor of a Group IV transition metal containing film forming composition;
b) exposing the substrate to a co-reactant; and
c) repeating the steps of a) and b) until a desired thickness of the Group IV transition metal containing film is deposited on the substrate using a vapor deposition process,

### TECHNICAL FIELD

The present invention relates to Group IV-containing film-forming compositions comprising Group IV-containing precursors, methods of synthesizing them and methods of using them to deposit the Group IV-containing films, in particular, to the Group IV-containing precursors containing cyclopentadiene (Cp) based ligands suitable for vapor phase depositions (e.g., ALD, CVD) of the Group IV-containing films.

### BACKGROUND

Semiconductor industry is looking to improve capacitance by changing materials with higher dielectric rates. This is because there is a limit to increasing the capacitance by widening the area or decreasing the thickness. Also, the Atomic Layer Deposition (ALD) has become a main deposition technique for thin films. To get desirable film properties (such as, low impurities, high uniformity, high quality) with the ALD technique, the most important aspect is precursor molecules. Among high-k dielectrics, Group IV based materials, such as TiO₂, HfO₂ and ZrO₂ are very promising. In the past, M(NR₂)₄(M=Ti, Hf, Zr) type precursors were used. However, they were not stable enough at high temperature and showed low step coverage.

WO2007141059 to Dussarrat et al. discloses alkylamide precursors containing cyclopentadienyl ligand to enhance the thermal stability.

More recently, KR100804413 discloses alkylamide zirconium precursor containing alkyl substituted cyclopentadienyl ligand.

Burger et al. (Journal of Organometallic Chemistry, 1975, 101, 295) discloses cyclopentadienyl substituted dialkylamido titanium complexes.

KR2080218 discloses M(Et₂Cp)(NMe₂)₃ for ALD process.

Cyclopentadienyl (Cp)-containing precursors have attracted attention, especially Group IV-containing Cp-containing precursors, suitable for vapor phase film deposition with high uniformity, high quality.

### SUMMARY

Disclosed are methods for forming a Group IV transition metal containing film, the method comprising the steps of:
a) exposing a substrate to a vapor of a Group IV transition metal containing film forming composition;
b) exposing the substrate to a co-reactant; and
c) repeating the steps of a) and b) until a desired thickness of the Group IV transition metal containing film is deposited on the substrate using a vapor deposition process,
wherein the Group IV transition metal containing film forming composition comprises a precursor having the formula:

M(R¹R²Cp)ₐ(L¹)_{b}

wherein, M is a Group IV transition metal selected from Zr, Hf or Ti;
Cp is cyclopentadiene;
R¹ and R² each are independently selected from the group consisting of H and —(CX₂)ₚCY₃, wherein X is independently H or F, Y is independently H or F, p is 0 to 10;
L¹ is −1 anionic ligand selected from halides, amidinate group, beta diketonate, non-fluorinated dienyl group, alkyl group, —OR³, —NR³R¹, wherein R³ and R⁴ each are independently selected from the group consisting of H and —(CX′₂)_{q}CY′₃, wherein X′ is independently H or F, Y′ is independently H or F, q is 0 to 10; and

a+b=4.
The disclosed methods may include one or more of the following aspects:
further comprising the steps of introducing an inert gas purge following the steps a) and b), respectively, to separate each exposure, wherein the inert gas purge uses an inert gas selected from N₂, Ar, Kr, or Xe;
further comprising the step of plasma treating the co-reactant;
the co-reactant being selected from O₂, O₃, H₂O, H₂O₂, NO, N₂O, NO₂, oxygen radicals thereof or mixtures thereof, or H₂, H₂CO, N₂H₄, NH₃, an amine, a hydrazine N(SiH₃)₃, radicals thereof or mixtures thereof;
the co-reactant being NH₃;
the co-reactant is being O₃;
the precursor being Hf(Me(Me)Cp)(NMe₂)₃;
the precursor being Hf(Me(Et)Cp)(NMe₂)₃;
the precursor being Hf(Me(nPr)Cp)(NMe₂)₃;
the precursor being Hf(Me(nBu)Cp)(NMe₂)₃;
the precursor being Zr(Me(Et)Cp)(NMe₂)₃;
the Group IV transition metal containing film being an oxide film;
the Group IV transition metal containing film being a nitride film;
the desired step coverage being 100%, perfect step coverage;
the aspect ratio ranging from approximately 2:1 to approximately 200:1;
the aspect ratio ranging from approximately 20:1 to approximately 200:1;
the aspect ratio ranging from approximately 30:1 to approximately 200:1;
the vapor deposition process being ALD, CVD or combination thereof;
the vapor deposition process being a spatial ALD, a thermal ALD, a plasma enhanced ALD and a plasma enhanced CVD;
the vapor deposition process being an ALD process;
the vapor deposition process being a CVD process;
the vapor deposition process being a spatial ALD;
the vapor deposition process being a thermal ALD;
the vapor deposition process being a PEALD;
the vapor deposition process being a PECVD;
a deposition temperature ranging from approximately 100° C. and approximately 600° C.;
the substrate being a powder;
the substrate being a patterned or 3D structure; and
the powder comprising one or more of NMC (Lithium Nickel Manganese Cobalt Oxide), LCO (Lithium Cobalt Oxide), LFP (Lithium Iron Phosphate), and other battery cathode materials.

Also disclosed are Group IV transition metal containing film forming compositions for a vapor deposition process comprising a precursor having the formula:

M(R¹R²Cp)ₐ(L¹)_{b}

wherein, M is a Group IV transition metal selected from Zr, Hf or Ti;
Cp is cyclopentadiene;
R¹ and R² each are independently selected from the group consisting of H and —(CX₂)ₚCY₃, wherein X is independently H or F, Y is independently H or F, p is 0 to 10;
L¹ is −1 anionic ligand selected from halides, amidinate group, beta diketonate, non-fluorinated dienyl group, alkyl group, —OR³, —NR³R⁴, wherein R³ and R⁴ each are independently selected from the group consisting of H and —(CX′₂)_{q}CY′₃, wherein X′ is independently H or F, Y′ is independently H or F, q is 0 to 10; and
a+b=4, The disclosed methods may include one or more of the following aspects:
each R¹, R², R³, and R⁴ being independently H, Me, Et, nPr, iPr, tBu, sBu, iBu, nBu, or tAmyl;
the precursor being Hf(Me(Me)Cp)(NMe₂)₃;
the precursor being Hf(Me(Et)Cp)(NMe₂)₃;
the precursor being Hf(Me(nPr)Cp)(NMe₂)₃;
the precursor being Hf(Me(nBu)Cp)(NMe₂)₃;
the precursor being Zr(Me(Et)Cp)(NMe₂)₃;
the Group IV transition metal containing film forming composition comprising between approximately 95% w/w and approximately 100.0% w/w of the precursor; and
the Group IV transition metal containing film forming composition comprising between approximately 0.0% w/w and approximately 5.0% w/w impurities.

Also disclosed are methods of forming a ZrO₂ film or coating by an ALD process on a substrate, the method comprising the steps of:
a) exposing the substrate to a vapor of Zr(Me(Et)Cp)(NMe₂)₃;
b) exposing the substrate to an oxidizer; and
e) repeating the steps of a) and b) until a desired thickness of the ZrO₂ film is deposited on the substrate using the ALD process. The disclosed methods may include one or more of the following aspects:
further comprising the steps of introducing an inert gas purge following the steps a) and b), respectively, to separate each exposure.

### Notation and Nomenclature

The following detailed description and claims utilize a number of abbreviations, symbols, and terms, which are generally well known in the art.

As used herein, the indefinite article “a” or “an” means one or more.

As used herein, “about” or “around” or “approximately” in the text or in a claim means ±10% of the value stated.

As used herein, “room temperature” in the text or in a claim means from approximately 20° C. to approximately 25° C.

The term “substrate” refers to a material or materials on which a process is conducted. The substrate may refer to a wafer having a material or materials on which a process is conducted. The substrates may be any suitable wafer used in semiconductor, photovoltaic, flat panel, or LCD-TFT device manufacturing. The substrate may also have one or more layers of differing materials already deposited upon it from a previous manufacturing step. For example, the wafers may include silicon layers (e.g., crystalline, amorphous, porous, etc.), silicon containing layers (e.g., SiO₂, SiN, SiON, SiCOH, etc.), metal containing layers (e.g., copper, cobalt, ruthenium, tungsten, platinum, palladium, nickel, ruthenium, gold, etc.) or combinations thereof. Furthermore, the substrate may be planar or patterned. The substrate may be an organic patterned photoresist film. The substrate may include layers of oxides which are used as dielectric materials in MEMS, 3D NAND, MIM, DRAM, or FeRam device applications (for example, ZrO₂ based materials, HfO₂ based materials, TiO₂ based materials, rare earth oxide based materials, ternary oxide based materials, etc.) or nitride-based films (for example, TaN, TiN, NbN) that are used as electrodes. One of ordinary skill in the art will recognize that the terms “film” or “layer” used herein refer to a thickness of some material laid on or spread over a surface and that the surface may be a trench or a line. Throughout the specification and claims, the wafer and any associated layers thereon are referred to as substrates.

The term “wafer” or “patterned wafer” refers to a wafer having a stack of films on a substrate and at least the top-most film having topographic features that have been created in steps prior to the deposition of the indium containing film.

The term “aspect ratio” refers to a ratio of the height of a trench (or aperture) to the width of the trench (or the diameter of the aperture).

Note that herein, the terms “film” and “layer” may be used interchangeably. It is understood that a film may correspond to, or related to a layer, and that the layer may refer to the film. Furthermore, one of ordinary skill in the art will recognize that the terms “film” or “layer” used herein refer to a thickness of some material laid on or spread over a surface and that the surface may range from as large as the entire wafer to as small as a trench or a line.

Note that herein, the terms “aperture”, “via”, “hole” and “trench” may be used interchangeably to refer to an opening formed in a semiconductor structure.

As used herein, the abbreviation “NAND” refers to a “Negative AND” or “Not AND” gate; the abbreviation “2D” refers to 2 dimensional gate structures on a planar substrate; the abbreviation “3D” refers to 3 dimensional or vertical gate structures, wherein the gate structures are stacked in the vertical direction.

Note that herein, the terms “deposition temperature” and “substrate temperature” may be used interchangeably. It is understood that a substrate temperature may correspond to, or be related to a deposition temperature, and that the deposition temperature may refer to the substrate temperature.

Note that herein, the terms “precursor” and “deposition compound” and “deposition gas” may be used interchangeably when the precursor is in a gaseous state at room temperature and ambient pressure. It is understood that a precursor may correspond to, or be related to a deposition compound or deposition gas, and that the deposition compound or deposition gas may refer to the precursor.

The standard abbreviations of the elements from the periodic table of elements are used herein. It should be understood that elements may be referred to by these abbreviation (e.g., Si refers to silicon, N refers to nitrogen, O refers to oxygen, C refers to carbon, H refers to hydrogen, F refers to fluorine, etc.).

The unique CAS registry numbers (i.e., “CAS”) assigned by the Chemical Abstract Service are provided to identify the specific molecules disclosed.

As used herein, the term “hydrocarbon” refers to a saturated or unsaturated function group containing exclusively carbon and hydrogen atoms. As used herein, the term “alkyl group” refers to saturated functional groups containing exclusively carbon and hydrogen atoms. An alkyl group is one type of hydrocarbon. Further, the term “alkyl group” refers to linear, branched, or cyclic alkyl groups. Examples of linear alkyl groups include without limitation, methyl groups, ethyl groups, propyl groups, butyl groups, etc. Examples of branched alkyls groups include without limitation, t-butyl. Examples of cyclic alkyl groups include without limitation, cyclopropyl groups, cyclopentyl groups, cyclohexyl groups, etc.

As used herein, the abbreviation “Me” refers to a methyl group; the abbreviation “Et” refers to an ethyl group; the abbreviation “Pr” refers to any propyl group (Le., n-propyl or isopropyl); the abbreviation “iPr” refers to an isopropyl group; the abbreviation “Bu” refers to any butyl group (n-butyl, iso-butyl, tert-butyl, sec-butyl); the abbreviation “tBu” refers to a tert-butyl group; the abbreviation “sBu” refers to a sec-butyl group; the abbreviation “iBu” refers to an iso-butyl group; the abbreviation “Ph” refers to a phenyl group; the abbreviation “Am” refers to any amyl group (iso-amyl, sec-amyl, tert-amyl); the abbreviation “Cy” refers to a cyclic hydrocarbon group (cyclobutyl, cyclopentyl, cyclohexyl, etc.); the abbreviation “Ar” refers to an aromatic hydrocarbon group (phenyl, xylyl, mesityl, etc.). As used in the disclosed embodiments, the term “independently” when used in the context of describing R groups should be understood to denote that the subject R group is not only independently selected relative to other R groups bearing the same or different subscripts or superscripts, but is also independently selected relative to any additional species of that same R group. For example in the formula MR¹ₓ(NR²R³)₍₄₋ₓ₎, where x is 2 or 3, the two or three R¹ groups may, but need not be identical to each other or to R² or to R³. Further, it should be understood that unless specifically stated otherwise, values of R groups are independent of each other when used in different formulas.

The term “substrate” refers to a material or materials on which a process is conducted. The substrate may refer to a wafer having a material or materials on which a process is conducted. The substrates may be any suitable wafer used in semiconductor, photovoltaic, flat panel, or LCD-TFT device manufacturing. The substrate may also have one or more layers of differing materials already deposited upon it from a previous manufacturing step. For example, the wafers may include silicon layers (e.g., crystalline, amorphous, porous, etc.), silicon containing layers (e.g., SiO₂, SiN, SiON, SiCOH, etc.), metal containing layers (e.g., copper, cobalt, ruthenium, tungsten, platinum, palladium, nickel, ruthenium, gold, etc.), an organic layer such as amorphous carbon, or a photoresist, or combinations thereof. Furthermore, the substrate may be planar or patterned. The substrate may include layers of oxides which are used as dielectric materials in MEMS, 3D NAND, MIM, DRAM, or FeRam device applications (for example, ZrO₂ based materials, HfO₂ based materials, TiO₂ based materials, rare earth oxide based materials, ternary oxide based materials, etc.) or nitride-based films (for example, TaN, TiN, NbN) that are used as electrodes. One of ordinary skill in the art will recognize that the terms “film” or “layer” used herein refer to a thickness of some material laid on or spread over a surface and that the surface may be a trench or a line. Throughout the specification and claims, the wafer and any associated layers thereon are referred to as substrates.

The term “wafer” or “patterned wafer” refers to a wafer having a stack of films on a substrate and at least the top-most film having topographic features that have been created in steps prior to the deposition of the indium containing film. The term “wafer” or “patterned wafer” may also refers to a trench wafer having an aspect ratio.

The term “aspect ratio” refers to a ratio of the height of a trench (or aperture) to the width of the trench (or the diameter of the aperture).

Note that herein, the terms “film” and “layer” may be used interchangeably. It is understood that a film may correspond to, or related to a layer, and that the layer may refer to the film. Furthermore, one of ordinary skill in the art will recognize that the terms “film” or “layer” used herein refer to a thickness of some material laid on or spread over a surface and that the surface may range from as large as the entire wafer to as small as a trench or a line.

Note that herein, the terms “aperture”, “gap”, “via”, “hole”, “opening”, “trench” and “structure” may be used interchangeably to refer to an opening formed in a semiconductor substrate.

Note that herein, the terms “deposition temperature”, “substrate temperature” and “process temperature” may be used interchangeably. It is understood that a substrate temperature may correspond to, or be related to a deposition temperature or a process temperature, and that the deposition temperature or process temperature may refer to the substrate temperature.

Note that herein, the terms “precursor” and “deposition compound” and “deposition gas” may be used interchangeably when the precursor is in a gaseous state at room temperature and ambient pressure. It is understood that a precursor may correspond to, or be related to a deposition compound or deposition gas, and that the deposition compound or deposition gas may refer to the precursor.

As used herein, the abbreviation “NAND” refers to a “Negated AND” or “Not AND” gate; the abbreviation “2D” refers to 2 dimensional gate structures on a planar substrate; the abbreviation “3D” refers to 3 dimensional or vertical gate structures, wherein the gate structures are stacked in the vertical direction.

Please note that the silicon-containing films, such as SiN and SiO, are listed throughout the specification and claims without reference to their proper stoichiometry. The silicon-containing films may include pure silicon (Si) layers, such as crystalline Si, poly-silicon (p-Si or polycrystalline Si), or amorphous silicon; silicon nitride (SiₖNₗ) layers; or silicon oxide (SiₙOₘ) layers; or mixtures thereof, wherein k, l, m, and n, inclusively range from 0.1 to 6. Preferably, silicon nitride is SiₖNₗ, where k and l each range from 0.5 to 1.5. More preferably, silicon nitride is Si₃N₄. Herein, SiN in the following description may be used to represent SiₖNₗ containing layers. Preferably, silicon oxide is SiₙOₘ, where n ranges from 0.5 to 1.5 and m ranges from 1.5 to 3.5. More preferably, silicon oxide is SiO₂. Herein, SiO in the following description may be used to represent SiₙOₘ containing layers. The silicon-containing film could also be a silicon oxide based dielectric material such as organic based or silicon oxide based low-k dielectric materials such as the Black Diamond II or III material by Applied Materials, Inc. with a formula of SiOCH. Silicon-containing film may also include SiₐO_{b}N_{c} where a, b, c range from 0,1 to 6. The silicon-containing films may also include dopants, such as B, C, P, As and/or Ge.

Ranges may be expressed herein as from about one particular value, and/or to about another particular value. When such a range is expressed, it is to be understood that another embodiment is from the one particular value and/or to the other particular value, along with all combinations within said range. Any and all ranges recited in the disclosed embodiments are inclusive of their endpoints (i.e., x=1 to 4 or x ranges from 1 to 4 includes x=1, x=4, and x=any number in between), irrespective of whether the term “inclusively” is used.

Reference herein to “one embodiment” or “an embodiment” means that a particular feature, structure, or characteristic described in connection with the embodiment may be included in at least one embodiment of the invention. The appearances of the phrase “in one embodiment” in various places in the specification are not necessarily all referring to the same embodiment, nor are separate or alternative embodiments necessarily mutually exclusive of other embodiments. The same applies to the term “implementation.”

As used herein, the term “independently” when used in the context of describing R groups should be understood to denote that the subject R group is not only independently selected relative to other R groups bearing the same or different subscripts or superscripts, but is also independently selected relative to any additional species of that same R group. For example in the formula MR¹ₓ (NR²R³)₍₄₋ₓ₎, where x is 2 or 3, the two or three R¹ groups may, but need not be identical to each other or to R² or to R³. Further, it should be understood that unless specifically stated otherwise, values of R groups are independent of each other when used in different formulas.

As used in this application, the word “exemplary” is used herein to mean serving as an example, instance, or illustration. Any aspect or design described herein as “exemplary” is not necessarily to be construed as preferred or advantageous over other aspects or designs. Rather, use of the word exemplary is intended to present concepts in a concrete fashion.

“Comprising” in a claim is an open transitional term which means the subsequently identified claim elements are a nonexclusive listing i.e. anything else may be additionally included and remain within the scope of “comprising.” “Comprising” is defined herein as necessarily encompassing the more limited transitional terms “consisting essentially of” and “consisting of”; “comprising” may therefore be replaced by “consisting essentially of” or “consisting of” and remain within the expressly defined scope of “comprising”.

Additionally, the term “or” is intended to mean an inclusive “or” rather than an exclusive “or”. That is, unless specified otherwise, or clear from context, “X employs A or B” is intended to mean any of the natural inclusive permutations. That is, if X employs A; X employs B; or X employs both A and B, then “X employs A or B” is satisfied under any of the foregoing instances. In addition, the articles “a” and “an” as used in this application and the appended claims should generally be construed to mean “one or more” unless specified otherwise or clear from context to be directed to a singular form.

“Providing” in a claim is defined to mean furnishing, supplying, making available, or preparing something. The step may be performed by any actors in the absence of express language in the claim to the contrary.

### BRIEF DESCRIPTION OF THE DRAWINGS

For a further understanding of the nature and objects of the present invention, reference should be made to the following detailed description, taken in conjunction with the accompanying drawings, in which like elements are given the same or analogous reference numbers and wherein:

FIG. 1 is TGA graphs of precursors illustrating the percentage of weight upon temperature increase;

FIG. 2 is differential scanning calorimetry (DSC) graphs of precursors;

FIG. 3 is vapor pressures of precursors at various temperatures;

FIG. 4 is a TGA graph of Zr(Me(Et)Cp)(NMe₂)₃ illustrating the percentage of weight upon temperature increase;

FIG. 5 is DSC of Zr(Me(Et)Cp)(NMe₂)₃, which are shown onset temperature of decomposition (325° C.) of the product;

FIG. 6 is a graph showing the formed HfO₂ film growth rate as a function of the chamber temperature using Hf(Me(nPr)Cp)(NMe₂)₃;

FIG. 7 is a graph showing the formed ZrO₂ film growth rate as a function of the chamber temperature using Zr(Me(Et)Cp)(NMe₂)₃; and

FIG. 8 is a photograph of SEM of NrO₂ films deposited in a patterned structure.

### DESCRIPTION OF PREFERRED EMBODIMENTS

Disclosed are Group IV transition metal containing film-forming compositions comprising Group IV transition metal precursors having the formula

M(R¹R²Cp)ₐ(L¹)_{b}

wherein
M is a Group IV transition metal selected from Zr, Hf or Ti;
Cp is cyclopentadiene;
R¹ and R² each are independently selected from the group consisting of H and —(CX₂)ₚCY₃, wherein X is independently H or F, Y is independently H or F, p=0 to 10;
L¹=−1 anionic ligands selected from halides, amidinate group, beta diketonate, non-fluorinated dienyl group, alkyl group, —OR³, —NR³R⁴, wherein R³ and R⁴ are independently selected from the group consisting of H and −(CX′₂)_{q}CY′₃, wherein X′ is independently H or F, Y′ is independently H or F, q=0 to 10; and

a+b=4.

Exemplary precursors containing the Group IV transition metal include; Hf(Me(Me)Cp)(NMe₂)₃, Hf(Me(Et)Cp)(NMe₂)₃, Hf(Me(nPr)Cp)(NMe₂)₃, Hf(Me(iPr)Cp)(NMe₂)₃, Hf(Me(nBu)Cp)(NMe₂)₃, Hf(Me(tBu)Cp)(NMe₂)₃, Hf(Me(iBu)Cp)(NMe₂)₃, Hf(Me(sBu)Cp)(NMe₂)₃, Hf(Me(Me)Cp)(NEt₂)₃, Hf(Me(Et)Cp)(NEt₂)₃, Hf(Me(nPr)Cp)(NEt₂)₃, Hf(Me(iPr)Cp)(NEt₂)₃, Hf(Me(nBu)Cp)(NEt₂)₃, Hf(Me(tBu)Cp)(NEt2)₃, Hf(Me(iBu)Cp)(NEt₂)₃, Hf(Me(sBu)Cp)(NEt₂)₃, Hf(Et(Me)Cp)(NMe₂)₃, Hf(Et(nPr)Cp)(NMe₂)₃, Hf(Et(iPr)Cp)(NMe₂)₃, Hf(Et(nBu)Cp)(NMe₂)₃, Hf(Et(tBu)Cp)(NMe₂)₃, Hf(Et(iBu)Cp)(NMe₂)₃, Hf(Et(sBu)Cp)(NMe₂)₃, Hf(Et(Me)Cp)(NEt₂)₃, Hf(Et(nPr)Cp)(NEt₂)₃, Hf(Et(iPr)Cp)(NEt₂)₃, Hf(Et(nBu)Cp)(NEt₂)₃, Hf(Et(tBu)Cp)(NEt₂)₃, Hf(Et(iBu)Cp)(NEt₂)₃, Hf(Et(sBu)Cp)(NEt₂)₃, Hf(CF₃(CF₃)Cp)(N(CF₃)₂)₃, Hf(CF₃(CF₂CF₃)Cp)(N(CF₃))₂)₃, Hf(CF₃(CF₂CF₂CF₃)Cp)(N(CF₃)₂)₃, Hf(CF₃(CF₂CF₂CF₂CF₃)Cp)(N(CF₃)₂)₃, Hf(CF₃(CF₃)Cp)(N(CF₂CF₃)₂)₃, Hf(CF₃(CF₂CF₃)Cp)(N(CF₂CF₃)₂)₃, Hf(CF₃(CF₂CF₂CF₃)Cp)(N(CF₂CF₃)₂)₂)₃, Hf(CF₃(CF₂CF₂CF₂CF₃)Cp)(N(CF₂CF₃)₂)₃, Hf(CF₃(CF₃)Cp)₂(N(CF₃)₂)₂, Hf(CF₃(CF₂CF₃)Cp)₂(N(CF₃)₂)₂, Hf(CF₃(CF₂CF₂CF₃)Cp)₂(N(CF₃)₂)₂, Hf(CF₃(CF₂CF₂CF₂CF₃)Cp)₂(N(CF₃)₂)₂, Hf(CF₃(CF₃)Cp)₂(N(CF₂CF₃)₂)₂, Hf(CF₃(CF₂CF₃)Cp)2(N(CF₂CF₃)₂)₂, Hf(CF₃(CF₂CF₂CF₃)Cp)₂(N(CF₂CF₃)₂)₂, Hf(CF₃(CF₂CF₂CF₂CF₃)Cp)₂(N(CF₂CF₃)₂)₂, Hf(CF₃(CF₃)Cp)₃(N(CF₃)₂), Hf(CF₃(CF₂CF₃)Cp)₃(N(CF₃)₂), Hf(CF₃(CF₂CF₂CF₃)Cp)₃(N(CF₃)₂), Hf(CF₃(CF₂CF₂CF₂CF₃)Cp)₃(N(CF₃)₂), Hf(CF₃(CF₃)Cp)₃(N(CF₂CF₃)₂), Hf(CF₃(CF₂CF₃)Cp)₃(N(CF₂CF₃)₂), Hf(CF₃(CF₂CF₂CF₃)Cp)₃(N(CF₂CF₃)₂), Hf(CF₃(CF₂CF₂CF₂CF₃)Cp)₃(N(CF₂CF₃)₂), Zr(Me(Me)Cp)(NMe₂)₃, Zr(Me(Et)Cp)(NMe₂)₃, Zr(Me(nPr)Cp)(NMe₂)₃, Zr(Me(iPr)Cp)(NMe₂)₃, Zr(Me(nBu)Cp)(NMe₂)₃, Zr(Me(tBu)Cp)(NMe₂)₃, Zr(Me(iBu)Cp)(NMe₂)₃, Zr(Me(sBu)Cp)(NMe₂)₃, Zr(Me(Me)Cp)(NEt₂)₃, Zr(Me(Et)Cp)(NEt₂)₃, Zr(Me(nPr)Cp)(NEt₂)₃, Zr(Me(iPr)Cp)(NEt₂)₃, Zr(Me(nBu)Cp)(NEt₂)₃, Zr(Me(tBu)Cp)(NEt₂)₃, Zr(Me(iBu)Cp)(NEt₂)₃, Zr(Me(sBu)Cp)(NEt₂)₃, Zr(Et(Me)Cp)(NMe₂)₃, Zr(Et(nPr)Cp)(NMe₂)₃, Zr(Et(iPr)Cp)(NMe₂)₃, Zr(Et(nBu)Cp)(NMe₂)₃, Zr(Et(tBu)Cp)(NMe₂)₃, Zr(Et(iBu)Cp)(NMe₂)₃, Zr(Et(sBu)Cp)(NMe₂)₃, Zr(Et(Me)Cp)(NEt₂)₃, Zr(Et(nPr)Cp)(NEt₂)₃, Zr(Et(iPr)Cp)(NEt₂)₃, Zr(Et(nBu)Cp)(NEt₂)₃, Zr(Et(tBu)Cp)(NEt₂)₃, Zr(Et(iBu)Cp)(NEt₂)₃, Zr(Et(sBu)Cp)(NEt₂)₃, Zr(CF₃(CF₃)Cp)(N(CF₃)₂)₃, Zr(CF₃(CF₂CF₃)Cp)(N(CF₃))₂)₃, Zr(CF₃(CF₂CF₂CF₃)Cp(N(CF₃)₂)₃, Zr(CF₃(CF₂CF₂CF₂CF₃)Cp)(N(CF₃)₂)₃, Zr(CF₃(CF₃)Cp)(N(CF₂CF₃)₂)₃, Zr(CF₃(CF₂CF₃)Cp)(N(CF₂CF₃)₂)₃, Zr(CF₃(CF₂CF₂CF₃)Cp)(N(CF₂CF₃)₂)₃, Zr(CF₃(CF₂CF₂CF₂CF₃)Cp)(N(CF₂CF₃)₂)₃, Zr(CF₃(CF₃)Cp)₂(N(CF₃)₂)₂, Zr(CF₃(CF₂CF₃)Cp)₂(N(CF₃)₂)₂, Zr(CF₃(CF₂CF₂CF₃)Cp)₂(N(CF₃)₂)₂, Zr(CF₃(CF₂CF₂CF₂CF₃)Cp)₂(N(CF₃)₂)₂, Zr(CF₃(CF₃)Cp)₂(N(CF₂CF₃)₂)₂, Zr(CF₃(CF₂CF₃)Cp)₂(N(CF₂CF₃)₂)₂, Zr(CF₃(CF₂CF₂CF₃)Cp)₂(N(CF₂CF₃)₂)₂, Zr(CF₃(CF₂CF₂CF₂CF₃)Cp)₂(N(CF₂CF₃)₂)₂, Zr(CF₃(CF₃)Cp)₃(N(CF₃)₂), Zr(CF₃(CF₂CF₃)Cp)₃(N(CF₃)₂), Zr(CF₃(CF₂CF₂CF₃)Cp)₃(N(CF₃)₂), Zr(CF₃(CF₂CF₂CF₂CF₃)Cp)₃(N(CF₃)₂), Zr(CF₃(CF₃)Cp)₃(N(CF₂CF₃)₂), Zr(CF₃(CF₂CF₃)Cp)₃(N(CF₂CF₃)₂), Zr(CF₃(CF₂CF₂CF₃)Cp)₃(N(CF₂CF₃)₂), Zr(CF₃(CF₂CF₂CF₂CF₃)Cp)₃(N(CF₂CF₃)₂), Ti(Me(Me)Cp)(NMe₂)₃, Ti(Me(Et)Cp)(NMe₂)₃, Ti(Me(nPr)Cp)(NMe₂)₃, Ti(Me(iPr)Cp)(NMe₂)₃, Ti(Me(nBu)Cp)(NMe₂)₃, Ti(Me(tBu)Cp)(NMe₂)₃, Ti(Me(iBu)Cp)(NMe₂)₃, Ti(Me(sBu)Cp)(NMe₂)₃, Ti(Me(Me)Cp)(NEt₂)₃, Ti(Me(Et)Cp)(NEt₂)₃, Ti(Me(nPr)Cp)(NEt₂)₃, Ti(Me(iPr)Cp)(NEt₂)₃, Ti(Me(nBu)Cp)(NEt₂)₃, Ti(Me(tBu)Cp)(NEt₂)₃, Ti(Me(iBu)Cp)(NEt₂)₃, Ti(Me(sBu)Cp)(NEt₂)₃, Ti(Et(Me)Cp)(NMe₂)₃, Ti(Et(nPr)Cp)(NMe₂)₃, Ti(Et(iPr)Cp)(NMe₂)₃, Ti(Et(nBu)Cp)(NMe₂)₃, Ti(Et(tBu)Cp)(NMe₂)₃, Ti(Et(iBu)Cp)(NMe₂)₃, Ti(Et(sBu)Cp)(NMe₂)₃, Ti(Et(Me)Cp)(NEt₂)₃, Ti(Et(nPr)Cp)(NEt₂)₃, Ti(Et(iPr)Cp)(NEt₂)₃, Ti(Et(nBu)Cp)(NEt₂)₃, Ti(Et(tBu)Cp)(NEt₂)₃, Ti(Et(iBu)Cp)(NEt₂)₃, Ti(Et(sBu)Cp)(NEt₂)₃, Ti(CF₃(CF₃)Cp)(N(CF₃)₂)₃, Ti(CF₃(CF₂CF₃)Cp)(N(CF₃))₂)₃, Ti(CF₃(CF₂CF₂CF₃)Cp)(N(CF₃)₂)₃, Ti(CF₃(CF₂CF₂CF₂CF₃)Cp)(N(CF₃)₂)₃, Ti(CF₃(CF₃)Cp)(N(CF₂CF₃)₂)₃, Ti(CF₃(CF₂CF₃)Cp)(N(CF₂CF₃)₂)₃, Ti(CF₃(CF₂CF₂CF₃)Cp)(N(CF₂CF₃)₂)₃, Ti(CF₃(CF₂CF₂CF₂CF₃)Cp)(N(CF₂CF₃)₂)₃, Ti(CF₃(CF₃)Cp)₂(N(CF₃)₂)₂, Ti(CF₃(CF₂CF₃)Cp)₂(N(CF₃)₂)₂, Ti(CF₃(CF₂CF₂CF₃)Cp)₂(N(CF₃)₂)₂, Ti(CF₃(CF₂CF₂CF₂CF₃)Cp)₂(N(CF₃)₂)₂, Ti(CF₃(CF₃)Cp)₂(N(CF₂CF₃)₂)₂, Ti(CF₃(CF₂CF₃)Cp)₂(N(CF₂CF₃)₂)₂, Ti(CF₃(CF₂CF₂CF₃)Cp)₂(N(CF₂CF₃)₂)₂, Ti(CF₃(CF₂CF₂CF₂CF₃)Cp)₂(N(CF₂CF₃)₂)₂, Ti(CF₃(CF₃)Cp)₃(N(CF₃)₂), Ti(CF₃(CF₂CF₃)Cp)₃(N(CF₃)₂), Ti(CF₃(CF₂CF₂CF₃)Cp)₃(N(CF₃)₂), Ti(CF₃(CF₂CF₂CF₂CF₃)Cp)₃(N(CF₃)₂), Ti(CF₃(CF₃)Cp)₃(N(CF₂CF₃)₂), Ti(CF₃(CF₂CF₃)Cp)₃(N(CF₂CF₃)₂), Ti(CF₃(CF₂CF₂CF₃)Cp)₃(N(CF₂CF₃)₂), and Ti(CF₃(CF₂CF₂CF₂CF₃)Cp)₃(N(CF₂CF₃)₂).

More preferably, the disclosed Group IV transition metal precursors are Hf(Me₂Cp)(NMe₂)₃, Hf((Et)MeCp)(NMe₂)₃, Hf(Me(nPr)Cp)(NMe₂)₃, Hf(Me(nBu)Cp)(NMe₂)₃, and Zr(Me(Et)Cp)(NMe₂)₃, Zr(Me₂Cp)(NMe₂)₃, Zr(Me(nPr)Cp)(NMe₂)₃, Zr(Me(nBu)Cp)(NMe₂)₃, or the like.

The disclosed also includes methods of synthesizing and using the disclosed precursors to deposit Group IV transition metal-containing films on substrates via vapor deposition processes.

The disclosed methods for syntheses of the disclosed Group IV transition metal-containing precursors include a reaction as shown in examples that follow. More specifically, the disclosed Group IV transition metal-containing precursors may be synthesized through a reaction of dialkylcyclopentadiene with the corresponding metal amides, for example, Ti(NR₂)₄, Zr(NR₂)₄, Hf(NR₂)₄, etc.

The disclosed Group IV transition metal-containing precursors may have good thermal stability and stabilization of total energy of the precursor. The bulkiness and electron donating effect from the dialky substituents on the cycleopentadienyl ring eventually could lead to high ALD windows, which make them suitable for Group IV transition metal-containing film depositions.

The disclosed Group IV transition metal-containing precursors may have high thermal stability and may be used for forming high-speed, high sensitivity semiconductor layers, e.g. in CMOS systems, 3D NAND Channel or in photodetectors. The disclosed Group IV transition metal-containing precursors and the disclosed film forming compositions are suitable to deposit the corresponding element-containing films and its related use for deposition of the corresponding element-containing layers.

Purity of the disclosed Group IV transition metal containing film-forming compositions is greater than 95% w/w (i.e., 95.0% w/w to 100.0% w/w), preferably greater than 98% w/w (i.e., 98.0% w/w to 100.0% w/w), and more preferably greater than 99% w/w (i.e., 99.0% w/w to 100.0% w/w). One of ordinary skill in the art will recognize that the purity may be determined by H NMR and gas liquid chromatography with mass spectrometry. The disclosed Group IV transition metal containing film-forming compositions may contain any of the following impurities: pyrazoles; pyridines; alkylamines; alkylimines; THF; ether; pentane; cyclohexane; heptanes; benzene; toluene; chlorinated metal compounds; lithium, sodium, potassium pyrazolyl. The total quantity of these impurities is preferably below 5% w/w (i.e., 0.0% w/w to 5.0% w/w), preferably below 2% w/w (i.e., 0.0% w/w to 2.0% w/w), and more preferably below 1% w/w (i.e., 0.0% w/w to 1.0% w/w). The composition may be purified by recrystallization, sublimation, distillation, and/or passing the gas liquid through a suitable adsorbent, such as a 4 Å molecular sieve.

Purification of the disclosed Group IV transition metal containing film-forming compositions may also result in metal impurities at the 0 ppbw to 1 ppmw, preferably 0-500 ppbw (part per billion weight) level. These metal impurities may include, but are not limited to, Aluminum (Al), Arsenic (As), Barium (Ba), Beryllium (Be), Bismuth (Bi), Cadmium (Cd), Calcium (Ca), Chromium (Cr), Cobalt (Co), Copper (Cu), Gallium (Ga), Germanium (Ge), Hafnium (Hf), Zirconium (Zr), Iron (Fe), Lead (Pb), Lithium (Li), Magnesium (Mg), Manganese (Mn), Tungsten (W), Nickel (Ni), Potassium (K), Sodium (Na), Strontium (Sr), Thorium (Th), Tin (Sn), Titanium (Ti), Uranium (U), Zinc (Zn) and the like.

Also disclosed are methods for forming Group IV transition metal-containing films on one or more substrates using a vapor deposition process. Applicants believe, and demonstrate in the Deposition Example that follows, that the disclosed Group IV transition metal containing film-forming compositions are suitable for atomic layer deposition (ALD). More particularly, the disclosed Group IV transition metal containing film-forming compositions are capable of surface saturation, self-limited growth per cycle, and perfect step coverage on aspects ratios ranging from approximately 2:1 to approximately 200:1, and preferably from approximately 20:1 to approximately 200:1. Additionally, the disclosed Group IV transition metal containing film-forming compositions have high decomposition temperatures, indicating good thermal stability to enable ALD. The high decomposition temperatures permit ALD at higher temperatures, resulting in films having higher purity.

The disclosed method may be useful in the manufacture of semiconductor, photovoltaic, LCD-TFT, flat panel type devices. The disclosed Group IV transition metal containing film-forming compositions may be used to deposit Group IV transition metal-containing films using any deposition methods known to those of skill in the art. Examples of suitable vapor deposition methods include chemical vapor deposition (CVD) atomic layer deposition (ALD). Exemplary CVD methods include thermal CVD, plasma enhanced CVD (PECVD), pulsed CVD (PCVD), low pressure CVD (LPCVD), sub-atmospheric CVD (SACVD) atmospheric pressure CVD (APCVD), hot-wire CVD (HWCVD, also known as cat-CVD, in which a hot wire serves as an energy source for the deposition process), radicals incorporated CVD, and combinations thereof. Exemplary ALD methods include thermal ALD, plasma enhanced ALD (PEALD), spatial ALD, hot-wire ALD (HWALD), radicals incorporated ALD, and combinations thereof, Super critical fluid deposition may also be used. The deposition method is preferably ALD, PE-ALD, spatial ALD in order to provide suitable step coverage and film thickness control,

The disclosed Group IV transition metal containing film-forming composition may be supplied either in neat form or in a blend with a suitable solvent, such as ethyl benzene, xylene, mesitylene, decalin, decane, dodecane. The disclosed precursors may be present in varying concentrations in the solvent.

The neat blended Group IV transition metal containing film-forming compositions are introduced into a reactor in vapor form by conventional means, such as tubing and/or flow meters. The vapor form may be produced by vaporizing the neat blended composition through a conventional vaporization step such as direct vaporization, distillation, by bubbling, or by using a sublimator, such as the one disclosed in PCT Publication WO2009/087609 to Xu et al. The neat blended composition may be fed in liquid state to a vaporizer where it is vaporized before it is introduced into the reactor. Alternatively, the neat blended composition may be vaporized by passing a carrier gas into a container containing the composition by bubbling the carrier gas into the composition. The carrier gas may include, but is not limited to, Ar, He, N₂, and mixtures thereof. Bubbling with a carrier gas may also remove any dissolved oxygen present in the neat blended composition. The carrier gas and composition are then introduced into the reactor as a vapor,

If necessary, the container containing the disclosed Group IV transition metal containing film-forming composition may be heated to a temperature that permits the composition to be in its liquid phase and to have a sufficient vapor pressure. The container may be maintained at temperatures in the range of, for example, approximately 0° C. to approximately 200° C. Those skilled in the art recognize that the temperature of the container may be adjusted in a known manner to control the amount of precursor vaporized.

The reactor may be any enclosure chamber within a device in which deposition methods take place such as without limitation, a parallel-plate type reactor, a cold-wall type reactor, a hot-wall type reactor, a single-wafer reactor, a multi-wafer reactor, other types of deposition systems under conditions suitable to cause the compounds to react and form the layers. One of ordinary skill in the art will recognize that any of these reactors may be used for either ALD or CVD deposition processes.

The reactor contains one more substrates onto which the films will be deposited. A substrate is generally defined as the material on which a process is conducted. The substrates may be any suitable substrate used in semiconductor, photovoltaic, fiat panel, LCD-TFT device manufacturing. Examples of suitable substrates include wafers, such as silicon, silica, glass, GaAs wafers. The wafer may have one more layers of differing materials deposited on it from a previous manufacturing step. For example, the wafers may include a dielectric layer. Furthermore, the wafers may include silicon layers (crystalline, amorphous, porous, etc.), silicon oxide layers, silicon nitride layers, silicon oxy nitride layers, carbon doped silicon oxide (SiCOH) layers, metal, metal oxide metal nitride layers (Ti, Ru, Ta, etc.) combinations thereof. Additionally, the wafers may include copper layers noble metal layers (e.g., platinum, palladium, rhodium, gold). The wafers may include barrier layers, such as manganese, manganese oxide, etc. Plastic layers, such as poly(3,4-ethylenedioxythiophene)poly(styrenesulfonate)[PEDOT:PSS] may also be used. The layers may be planar or patterned. The disclosed processes may deposit the Group V (five)-containing layer directly on the wafer or directly on one or more layers on top of the wafer (when patterned layers form the substrate). Furthermore, one of ordinary skill in the art will recognize that the terms “film” “layer” used herein refer to a thickness of some material laid on spread over a surface and that the surface may be a trench a line. Throughout the specification and claims, the wafer and any associated layers thereon are referred to as substrates. For example, a Niobium oxide film may be deposited onto a metal oxide layer, such as a ZrO₂ layer, an HfO₂ layer, a MoO₂ layer. In subsequent processing, another metal oxide layer may be deposited on the Niobium oxide layer to form a laminate; for example, ZrO₂/Nb₂O₅/ZrO₂ laminate dielectric stack are typical of DRAM high-k stack. A conductive metal nitride layer, such as a Niobium Nitride layer or a Titanium Nitride layer, may be deposited before on the last metal oxide layer to form, respectively, the bottom and top electrodes. The resulting NbN/ZrO₂O₅/ZrO₂/NbN stack may be used in DRAM capacitors. Other conductive films, such as RuO, Ru, Pt, Ir, WN, WNC, may be also used as the bottom top electrodes, alone in addition to the NbN or TaN layers. The substrate may be a patterned or 3D structure.

The substrate may also be a powder, such as the powder used in rechargeable battery technology. A non-limiting number of powder materials include NMC (Lithium Nickel Manganese Cobalt Oxide), LCO (Lithium Cobalt Oxide), LFP (Lithium Iron Phosphate), and other battery cathode materials.

The temperature and the pressure within the reactor are held at conditions suitable for ALD. In other words, after introduction of the vaporized disclosed composition into the chamber, conditions within the chamber are such that at least part of the precursor is deposited onto the substrate to form a Group IV transition metal containing layer. For instance, the pressure in the reactor or the deposition pressure may be held between about 10⁻³ torr and about 100 Torr, more preferably between about 10⁻² and 100 Torr, as required per the deposition parameters. Likewise, the temperature in the reactor or the deposition temperature may be held between about 100° C. and about 600° C., preferably between about 150° C. and about 500° C. One of ordinary skill in the art will recognize that “at least part of the precursor is deposited” means that some all of the precursor reacts with adheres to the substrate.

The temperature of the reactor may be controlled by either controlling the temperature of the substrate holder controlling the temperature of the reactor wall. Devices used to heat the substrate are known in the art. The reactor wall is heated to a sufficient temperature to obtain the desired film at a sufficient growth rate and with desired physical state and composition. A non-limiting exemplary temperature range to which the reactor wall may be heated includes from approximately 50° C. to approximately 600° C. When a plasma deposition process is utilized, the deposition temperature may range from approximately 150° C. to approximately 500° C. Alternatively, when a thermal process is performed, the deposition temperature may range from approximately 100° C. to approximately 600° C.

In addition to the disclosed Group IV transition metal-containing film-forming composition, a co-reactant may be introduced into the reactor. When the target is a conductive film, the co-reactant may be H₂, H₂CO, N₂H₄, NH, a primary amine, a secondary amine, a tertiary amine, trisilylamine, radicals thereof, and mixtures thereof. Preferably, the co-reactant is H₂ NH₃.

Alternatively, when the target is a dielectric film, the co-reactant may be an oxidizing gas such as one of O₂, O₃, H₂O, H₂O₂, NO, N₂O, NO₂, oxygen containing radicals such as O— OH—, carboxylic acids, formic acid, acetic acid, propionic acid, and mixtures thereof. Preferably, the oxidizing gas is selected from the group consisting of O₃, H₂O₂ H₂O.

The co-reactant may be treated by a plasma, in order to decompose the reactant into its radical form, N₂ may also be utilized as a nitrogen source gas when treated with plasma. For instance, the plasma may be generated with a power ranging from about 10 W to about 1000 W, preferably from about 50 W to about 500 W. The plasma may be generated present within the reactor itself. Alternatively, the plasma may generally be at a location removed from the reactor, for instance, in a remotely located plasma system. One of skill in the art will recognize methods and apparatus suitable for such plasma treatment.

For example, the co-reactant may be introduced into a direct plasma reactor, which generates plasma in the reaction chamber, to produce the plasma-treated reactant in the reaction chamber. Exemplary direct plasma reactors include the Titan™ PECVD System produced by Trion Technologies. The co-reactant may be introduced and held in the reaction chamber prior to plasma processing. Alternatively, the plasma processing may occur simultaneously with the introduction of the reactant. In-situ plasma is typically a 13.56 MHz RF inductively coupled plasma that is generated between the showerhead and the substrate holder. The substrate the showerhead may be the powered electrode depending on whether positive ion impact occurs. Typical applied powers in in-situ plasma generators are from approximately 30 W to approximately 1000 W. Preferably, powers from approximately 30 W to approximately 600 W are used in the disclosed methods. More preferably, the powers range from approximately 100 W to approximately 500 W. The disassociation of the co-reactant using in-situ plasma is typically less than achieved using a remote plasma source for the same power input and is therefore not as efficient in reactant dissociation as a remote plasma system, which may be beneficial for the deposition of Group IV transition metal-containing films on substrates easily damaged by plasma.

Alternatively, the plasma-treated co-reactant may be produced outside of the reaction chamber, for example, a remote plasma to treat the co-reactant prior to passage into the reaction chamber.

The ALD conditions within the chamber allow the disclosed Group IV transition metal-containing film forming composition adsorbed chemisorbed on the substrate surface to react and form a Group IV transition metal-containing film on the substrate. In some embodiments, Applicants believe that plasma-treating the co-reactant may provide the co-reactant with the energy needed to react with the disclosed Group IV transition metal-containing film forming composition.

Depending on what type of film is desired to be deposited, an additional precursor compound may be introduced into the reactor. The additional precursor may be used to provide additional elements to the Group IV transition metal-containing film. The additional elements may include Group I elements (lithium, Sodium, potassium), lanthanides (Ytterbium, Erbium, Dysprosium, Gadolinium, Praseodymium, Cerium, Lanthanum, Yttrium), Group IV elements (zirconium, titanium, hafnium), main group elements (germanium, silicon, aluminum), additional different Group V elements, and mixtures thereof. When an additional precursor compound is utilized, the resultant film deposited on the substrate contains the Group V metal in combination with an additional element. When the additional precursor and the Group IV transition metal-containing precursors are used in more than one ALD super cycle sequences, a nanolaminate film is obtained. For instance, when an additional Li-containing precursor is used, the Group IV transition metal-containing film will contain Li, such as, a lithium noibiate (LiNbO₃) film. One of ordinary skilled in the art will recognize the Group IV transition metal-containing films containing Li may be formed by ALD on any types of substrates including a powder.

The disclosed Group IV transition metal-containing film forming composition and co-reactants may be introduced into the reactor either simultaneously (CVD), sequentially (ALD) or different combinations thereof. The reactor may be purged with an inert gas (e.g., N₂ or Ar) between the introduction of the film forming composition and the introduction of the co-reactant. The reactor may be purged with an inert gas between the introduction of each of the Group IV transition metal-containing film forming composition, any additional precursors, and the co-reactants. Another example is to introduce the co-reactant continuously and to introduce the Group IV transition metal-containing film forming composition by pulse (pulsed CVD), while activating the co-reactant sequentially with a plasma, provided that the Group IV transition metal-containing film forming composition and the non-activated co-reactant do not substantially react at the chamber temperature and pressure conditions (CW PEALD).

Each pulse of the disclosed Group IV transition metal-containing film forming composition may last for a time period ranging from about 0.01 seconds to about 120 seconds, alternatively from about 1 seconds to about 80 seconds, alternatively from about 5 seconds to about 30 seconds. The co-reactant may also be pulsed into the reactor. In such embodiments, the pulse of each may last for a time period ranging from about 0.01 seconds to about 120 seconds, alternatively from about 1 seconds to about 30 seconds, alternatively from about 2 seconds to about 20 seconds. In another alternative, the vaporized Group IV transition metal-containing film forming compositions and co-reactants may be simultaneously sprayed from different sectors of a shower head (without mixing of the composition and the reactant) under which a susceptor holding several wafers is spun (spatial ALD).

Depending on the particular process parameters, deposition may take place for a varying length of time. Generally, deposition may be allowed to continue as long as desired necessary to produce a film with the necessary properties. Typical film thicknesses may vary from several angstroms to several hundreds of microns, and typically from 2 to 100 nm, depending on the specific deposition process. The deposition process may also be performed as many times as necessary to obtain the desired film.

In one non-limiting exemplary ALD process, the vapor phase of the disclosed Group IV transition metal-containing film forming composition is introduced into the reactor, where it is contacted with a suitable substrate. Excess composition may then be removed from the reactor by purging and/or evacuating the reactor, that is, either by purging a reactor with an inert gas (e.g., N₂, Ar, Kr or Xe), or passing the substrate in a sector under high vacuum and/or a carrier gas curtain. A co-reactant (for example, O₃) is introduced into the reactor where it reacts with the absorbed Group IV transition metal-containing film forming composition in a self-limiting manner. Any excess co-reactant is removed from the reactor by purging and/or evacuating the reactor. If the desired film is a Group IV transition metal-containing oxide, this two-step process may provide the desired film thickness may be repeated until a film having the necessary thickness has been obtained.

Alternatively, if the desired film contains the Group IV transition metal and a second element, such as Li, the two-step process above may be followed by introduction of the vapor of an additional precursor compound into the reactor. The additional precursor compound will be selected based on the nature of the Group IV transition metal-containing film being deposited. After introduction into the reactor, the additional precursor compound is contacted with the substrate. Any excess precursor compound is removed from the reactor by purging and/or evacuating the reactor. Once again, a co-reactant may be introduced into the reactor to react with the precursor compound. Excess co-reactant is removed from the reactor by purging and/or evacuating the reactor. If a desired film thickness has been achieved, the process may be terminated. However, if a thicker film is desired, the entire four-step process may be repeated. By alternating the provision of the Group V (five)-containing film forming composition, additional precursor compound, and co-reactant, a film of desired composition and thickness can be deposited. In one non-limiting exemplary ALD process, the vapor phase of one of the disclosed Group IV transition metal-containing film forming composition, for example (t-butylimido)(methylcyclopentadienyl)bis (isopropylpyrazolate)Niobium(V), Nb(=NtBu)(MeCp)(iPr-pyz)₂, is introduced into the reactor, where it is contacted with a powder substrate. Excess composition may then be removed from the reactor by purging and/or evacuating the reactor. A co-reactant (for example, O₃) is introduced into the reactor where it reacts with the absorbed Nb(=NtBu)(MeCp)(iPr-pyz)₂ in a self-limiting manner to form a Nb oxide film. Any excess O₃ gas is removed from the reactor by purging and/or evacuating the reactor. A Li-containing precursor may then be exposed to the powder substrate and/or the Nb oxide film to form a Li and Nb oxide film LiNbO₃. For example, LiOtBu, may serve as the Li precursor. This non-limiting exemplary ALD process described above using Nb(=NtBu)(MeCp)(iPr-pyz)₂, O₃ and LiOtBu may then be repeated on the powder until a desired thickness of the LiNbO₃ film deposited on the powder. The resulting LiNbO₃ film may be used in rechargeable battery applications. One of ordinary skilled in the art will recognize that the suitable lithium precursors include, but are not limited to, LiOtBu, LiN(SiR₃)₂ wherein each R is selected from H, a C₁ to C₄ alkyl or alkenyl group, Li(DPM) (lithium dipivaloylmethane aka lithium 2,2,6,6-tetramethyl-3,5-heptanedionate) or any other suitable lithium ALD precursors.

When the co-reactant in this exemplary ALD process is treated with a plasma, the exemplary ALD process becomes an exemplary PEALD process. The co-reactant may be treated with plasma prior subsequent to introduction into the chamber.

In a second non-limiting exemplary ALD process, the vapor phase of one of the disclosed Group IV transition metal-containing film forming composition, for example Zr(Me(Et)Cp)(NMe₂)₃, is introduced into the reactor, where it is contacted with a Si substrate. Excess composition may then be removed from the reactor by purging an inert gas (e.g., N₂, Ar, Kr or Xe) and/or evacuating the reactor. A co-reactant (for example, O₃) is introduced into the reactor where it reacts with the absorbed Group IV transition metal-containing film forming composition in a self-limiting manner to form a Group IV transition metal-containing oxide film. Any excess O₃ gas is removed from the reactor by purging and/or evacuating the reactor. These two steps may be repeated until the Group IV transition metal-containing oxide film obtains a desired thickness, typically around 10 angstroms.

In another exemplary ALD process, another precursor may be introduced sequentially between one several ALD super-cycles (e.g., O-containing co-reactant/Group IV transition metal-containing precursor/O-containing co-reactant) in order to deposit a Group IV transition metal-containing MO film and Group IV transition metal-containing O/MO nanolaminate, M being selected from a Group IV element, a different group V (five) element, silicon, germanium, vanadium, niobium, tantalum, aluminum, or any lanthanide and alkali metals, alkali earth metals, chalcogens. The M precursor selected preferably undergoes ALD growth in the same temperature window exhibited by the selected Group IV transition metal-containing film forming composition.

Upon obtaining a desired film thickness, the film may be subject to further processing, such as thermal annealing, furnace-annealing, rapid thermal annealing, UV e-beam curing, and/or plasma gas exposure. Those skilled in the art recognize the systems and methods utilized to perform these additional processing steps. For example, the Zro₂, TiO₂, HfO₂ films may be exposed to a temperature ranging from approximately 150° C. and approximately 1000° C. for a time ranging from approximately 0.1 second to approximately 7200 seconds under an inert atmosphere, an O-containing atmosphere, combinations thereof. Most preferably, the temperature is 400° C. for 3600 seconds under an inert atmosphere or an O-containing atmosphere. The resulting film may contain fewer impurities and therefore may have an improved density resulting in improved leakage current. The annealing step may be performed in the same reaction chamber in which the deposition process is performed. Alternatively, the substrate may be removed from the reaction chamber, with the annealing/flash annealing process being performed in a separate apparatus. Any of the above post-treatment methods, but especially thermal annealing, has been found effective to reduce carbon and nitrogen contamination of the Nb₂O₅ film. This in turn tends to improve the resistivity of the film.

After annealing, the Group IV transition metal-containing films deposited by any of the disclosed processes may have a bulk resistivity at room temperature of approximately 50 μohm,cm to approximately 1,000 μohm,cm. Room temperature is approximately 20° C. to approximately 28° C. depending on the season. Bulk resistivity is also known as volume resistivity. One of ordinary skill in the art will recognize that the bulk resistivity is measured at room temperature on the Group IV transition metal-containing films that are typically approximately 50 nm thick. The bulk resistivity typically increases for thinner films due to changes in the electron transport mechanism. The bulk resistivity also increases at higher temperatures.

### EXAMPLES

The following non-limiting examples are provided to further illustrate embodiments of the invention. However, the examples are not intended to be all inclusive and are not intended to limit the scope of the inventions described herein.

### Example 1: Synthesis of Hf(Me₂Cp)(NMe₂)₃

Synthesis of Dimethylcyclopentadiene: Methyl cyclopentadiene (20 g, 0.250 mol) was dissolved in 150 mL of THF and cooled to −78° C. and n-butyllithium (2.5M in Hexane) (104 mL, 0.261 mol) was added to the methyl cyclopentadienyl solution. The mixture was stirred at room temperature for 3 hrs. After 3 hrs, iodo methane (32.21 g, 0.227 mol) dissolved in 30 mL of THF was added to the lithiated methyl cyclopentadiene solution at −78° C. The mixture was stirred at room temperature for overnight. The mixture was extracted with diethyl ether and the organic layer was dried with MgSO₄. The filtration was concentrated under vacuum condition and 20 g of crude state of dimethyl cyclopentadiene was obtained as a reddish brown liquid. The crude product is then purified by distillation up to 27° C. under vacuum condition to give 5.4 g (25%) of yellow liquid. The material was characterized by ¹H NMR: (ppm) in C₆D₆: [6.44˜5.79(m, 2H)], [2.72, 2.71, 2.67(m, 2H)], [1.90, 1.84, 1.79(m, 6H)].

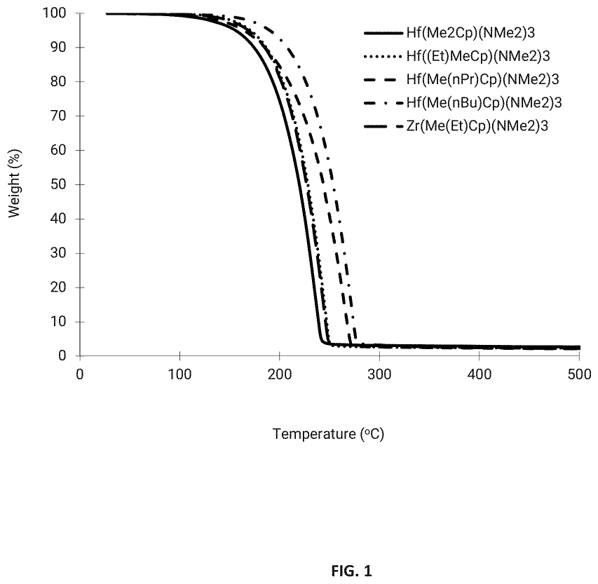

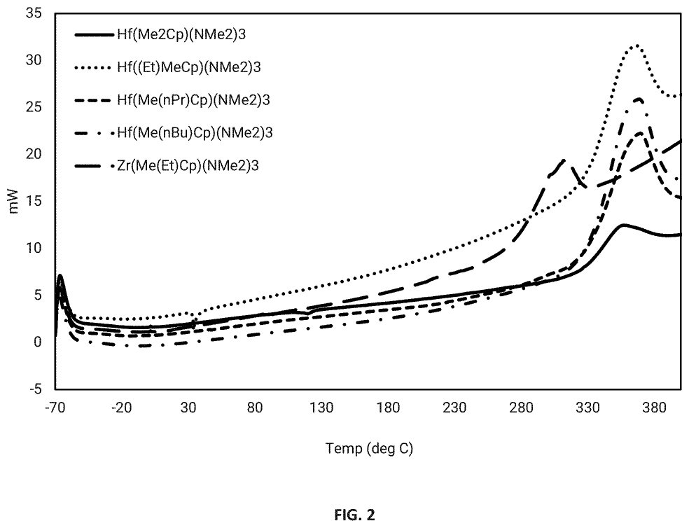

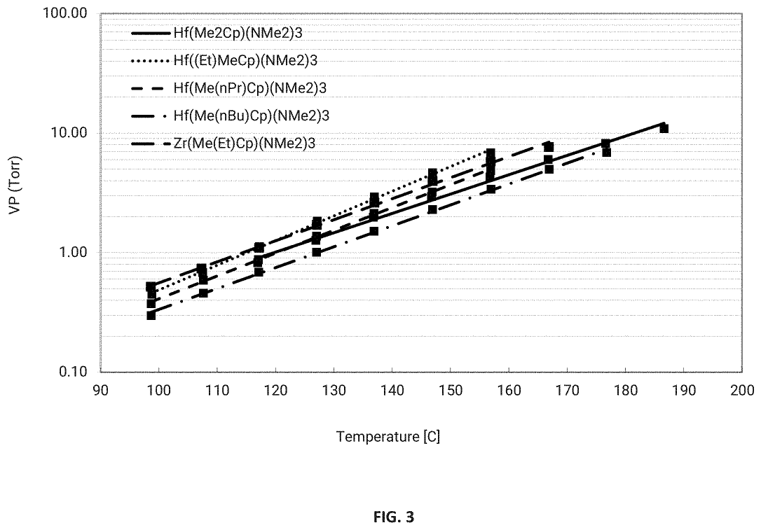

Synthesis of Hf(Me₂Cp)(NMe₂)₃: TDMAHf (10 g, 0.028 mol) and 50 mL of toluene were added in the schlenk flask and cooled to −78° C. TDMAHf is Tetrakis(dimethylamido)hafnium(IV) (CAS No. is 19782-68-4). Dimethylcyclopentadiene ligand (2.7 g, 0.029 mol) was added to the TDMAHf solution. The mixture was stirred for overnight at room temperature. After the reaction, the solution was removed under vacuum condition. The crude was yellow slurry. The crude product was then purified by sublimation up to 96° C. @ 50 mTorr to give 7.84 g (69%) of gelatinous yellow solid. The material was characterized by ¹H NMR: (ppm) in C₆D₆: [5.89˜5.72(m, 3H)], [2.99(s) 2.99(s) (18H)], [2.11(s), 2.00(s) (6H)], The purified product left a 2.1% residual mass during open-cup TGA analysis measured at a temperature rising rate of 10° C./min in an atmosphere which flows nitrogen at 200 mL/min. These results are shown in FIG. 1, which is a TGA graph illustrating the percentage of weight upon temperature increase. Onset temperature of decomposition (325° C.) of the product was measured by DSC, which are shown in FIG. 2. FIG. 3 shows the vapor pressure of Hf(Me₂Cp)(NMe₂)₃ at various temperatures.

### Example 2: Synthesis of Hf((Et)MeCp)(NMe₂)₃

Synthesis of ethylmethyl cyclopentadiene: methyl cyclopentadiene (19 g, 0.237 mol) was dissolved in 110 mL of THF and cooled to −78° C. and n-butyllithium (2.5M in Hexane) (99.16 mL, 0.248 mol) was added to the methyl cyclopentadienyl solution. The mixture was stirred at room temperature for 3 hrs. After 3 hrs, iodo ethane (33.62 g, 0.216 mol) dissolved in 50 mL of THF was added to the lithiated methyl cyclopentadiene solution at −78° C. The mixture was stirred at room temperature for overnight. The mixture was extracted with diethyl ether and the organic layer was dried with MgSO₄. The filtration was concentrated under vacuum condition and crude state of ethylmethyl cyclopentadiene was obtained as a reddish brown liquid. The material is then purified by distillation up to 35° C. under vacuum condition to give 11 g (47%) of yellow liquid. The material was characterized by ¹H NMR: (ppm) in C₆D₆: [6.33˜5.98(m, 2H)], [2.74˜2.67(m, 2H)], [2.31˜2.15(m, 2H)], [1.93˜1.81(m, 3H)], [1.11(t), 1.04(t), 0.96(t) (3H)].

Synthesis of Hf((Et)MeCp)(NMe₂)₃: TDMAHf (10 g, 0.028 mol) and 50 mL of toluene were added in the schlenk flask and cooled to −78° C. Ethylmethyl cyclopentadiene ligand (3.35 g, 0.031 mol) was added to the TDMAHf solution. The mixture was stirred for overnight at room temperature. After the reaction, the solution was removed under vacuum condition. The crude was yellow liquid. The material was then purified by distillation up to 115° C.@35 mTorr to give 6.34 g (53.2%) of white gelatinous solid. The crude product was characterized ¹H NMR: (ppm) in C₆D₆: [5.92˜5.72(m, 3H)], [2.99(s) 2.98(s) (18H)], [2.49(q), 2.40(q) (2H)], [2.12(s), 2.02(s) (3H)], [1.14(t), 1.09(t) (3H)]. The purified product left a 2.3% residual mass during open-cup TGA analysis measured at a temperature rising rate of 10° C./min in an atmosphere which flows nitrogen at 200 mL/min. These results are shown in FIG. 1, which is a TGA graph illustrating the percentage of weight upon temperature increase. Onset temperature of decomposition (325° C.) of the product was measured by DSC, which are shown in FIG. 2. FIG. 3 shows the vapor pressure of Hf((Et)MeCp)(NMe₂)₃ at various temperatures.

### Example 3: Synthesis of Hf(Me(nPr)Cp)(NMe₂)₃

Synthesis of methylpropyl cyclopentadiene: Methyl cyclopentadiene (23 g, 0.286 mol) was dissolved in 120 mL of THF and cooled to −78° C. and n-butyllithium (2.5M in Hexane) (120 mL, 0.299 mol) was added to the methyl cyclopentadienyl solution. The mixture was stirred at room temperature for 3 hrs. After 3 hrs, 1-bromopropane (32 g, 0.260 mol) dissolved in 50 mL of THF was added to the lithiated methyl cyclopentadiene solution at −78° C. The mixture was stirred at room temperature for overnight. The mixture was extracted with diethyl ether and the organic layer was dried with MgSO₄. The filtration was concentrated under vacuum condition and crude state of methylpropyl cyclopentadiene was obtained as a brown liquid. The material is then purified by distillation up to 50° C. under vacuum condition to give 13.4 g (42%) of yellow liquid. The material was characterized by ¹H NMR: (ppm) in C₆D₆: [6.42˜5.80(m, 2H)], [2.76˜2.68(m, 2H)], [2.29˜2.17(m, 2H)], [1.93˜1.82(m, 3H)], [159˜1.36(m, 2H)], [0.94˜0.79(m, 3H)].

Synthesis of Hf(Me(nPr)Cp)(NMe₂)₃: TDMAHf (23.55 g, 0.066 mol) and 100 mL of toluene were added in the schlenk flask and cooled to −78° C. Methylpropyl cyclopentadiene ligand (8.92 g, 0.073 mol) was added to the TDMAHf solution. The mixture was stirred for overnight at room temperature. After the reaction, the solution was removed under vacuum condition. The crude was yellow liquid. The material was then purified by distillation up to 120° C.@45mTorr to give 22.1 g (77%) of yellow liquid. The crude product was characterized by ¹H NMR: δ(ppm) in C₆D₆: [5.93˜5.73(m, 3H)], [3.00(s) 3.00(s) (18H)], [2.47(t), 2.43(t), 2.41(t) (2H)], [2.12(s), 2.04(s) (3H)], [1.60˜1.45(m, 2H)], [0.91(t), 0.89(t) (3H)]. The purified product left a 2.0% residual mass during open-cup TGA analysis measured at a temperature rising rate of 10° C./min in an atmosphere which flows nitrogen at 200 mL/min. These results are shown in FIG. 1, which is a TGA graph illustrating the percentage of weight upon temperature increase. Onset temperature of decomposition (325° C.) of the product was measured by DSC, which are shown in FIG. 2. FIG. 3 shows the vapor pressure of Hf(Me(nPr)Cp)(NMe₂)₃ at various temperatures.

### Example 4: Synthesis of Hf(Me(nBu)Cp)(NMe₂)₃

Synthesis of butylmethyl cyclopentadiene: Methyl cyclopentadiene (25 g, 0.312 mol) was dissolved in 130 mL of THF and cooled to −78° C. and n-butyllithium (2.5M in Hexane) (130.4 mL, 0.326 mol) was added to the methyl cyclopentadienyl solution. The mixture was stirred at room temperature for 3 hrs. After 3 hrs, 1-bromobutane (38.86 g, 0.284 mol) dissolved in 60 mL of THF was added to the lithiated methyl cyclopentadiene solution at −78° C. The mixture was stirred at room temperature for overnight. The mixture was extracted with diethyl ether and the organic layer was dried with MgSO₄. The filtration was concentrated under vacuum condition and crude state of butylmethyl cyclopentadiene was obtained as a brown liquid. The material is then purified by distillation up to 55° C. under vacuum condition to give 17.96 g (47%) of yellow liquid. The material was characterized by ¹H NMR: ˜(ppm) in C₆D₆: [6.44˜5.81(m, 2H)], [2.78˜2.55(m, 2H)], [2.32˜2.21(m, 2H)], [1.94˜1.84(m, 3H)], [1.47˜1.32(m, 2H)], [1.30˜1.15(m, 2H)], [0.92˜0.84(m, 3H)].

Synthesis of Hf(Me(nBu)Cp)(NMe₂)₃: TDMAHf (10 g, 0.028 mol) and 50 mL of toluene were added in the schlenk flask and cooled to −78° C. Butylmethyl cyclopentadiene ligand (4.22 g, 0.031 mol) was added to the TDMAHf solution. The mixture was stirred for overnight at room temperature. After the reaction, the solution was removed under vacuum condition. The crude was yellow liquid. The material was then purified by distillation up to 130° C.@50 mTorr to give 7.28 g (58%) of yellow liquid. The crude product was characterized by ¹H NMR: δ(ppm) in C₆D₆: [5.93˜5.74(m, 3H)], [3.01(s) 3.00(s) (18H)], [2.51(t), 2.47(t), 2.46(t) (2H)], [2.13(s), 2.06(s) (3H)], [1.57˜1.43(m, 2H)], [1.36˜1.25(m, 2H)], [0.90(t), 0.89(t) (3H)]. The purified product left a 2.1% residual mass during open-cup TGA analysis measured at a temperature rising rate of 10° C./min in an atmosphere which flows nitrogen at 200 mL/min. These results are shown in FIG. 1, which is a TGA graph illustrating the percentage of weight upon temperature increase. Onset temperature of decomposition (326° C.) of the product was measured by DSC, which are shown in FIG. 2. FIG. 3 shows the vapor pressure of Hf(Me(nBu)Cp)(NMe₂)₃ at various temperatures. Table 1 lists the synthesized Hf precursors.

TABLE 1

| Structure | 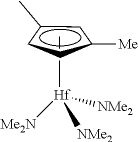 | 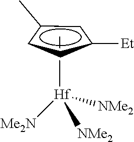 | 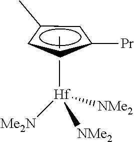 | 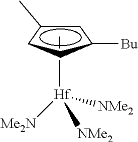 |
|---|---|---|---|---|
| Formula | Hf(Me(Me)Cp) | Hf(Me(Et)Cp) | Hf(Me(nPr)(Cp) | Hf(Me(nBu)Cp) |
| | (NMe₂)₃ | (NMe₂)₃ | (NMe₂)₃ | (NMe₂)₃ |
| Appearance | gel | gel | liquid | liquid |
| Vapor Pressure | 1 Torr @ 120° C. | 1 Torr @ 115° C. | 1 Torr @ 120° C. | 1 Torr @ 127° C. |
| Decomposed | 325° C. | 325° C. | 325° C. | 326° C. |
| TG residue | 2.1% | 2.3% | 2.0% | 2.1% |

### Example 5: Synthesis of Zr(Me(Et)Cp)(NMe₂)₃

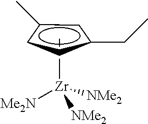

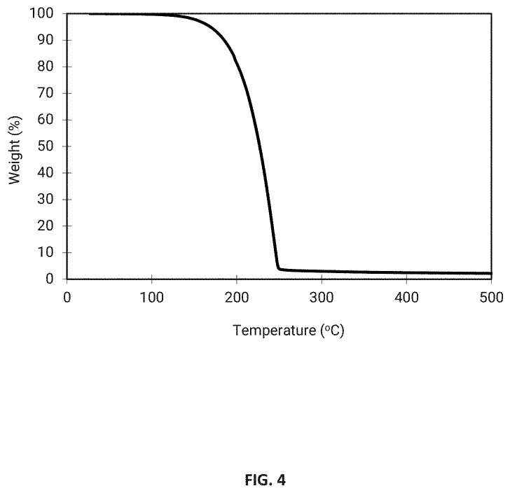

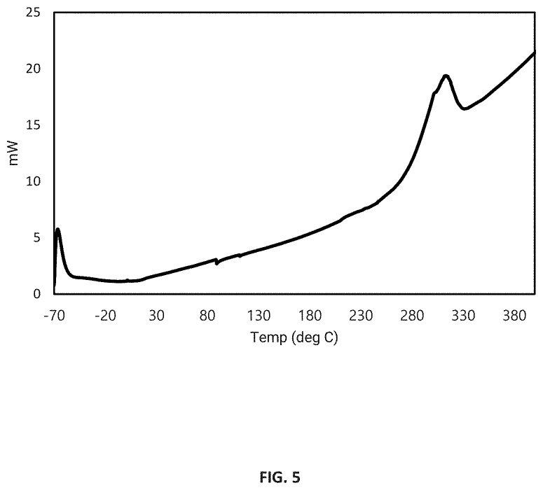

TDMAZr (27 g, 0.101 mol) and 130 mL of toluene were added in the schlenk flask and cooled to −78° C. TDMAZr is Tetrakis(dimethylamido)zirconium(IV) (CAS No.: 19756-04-8). Ethylmethyl cyclopentadiene ligand (12 g, 0.111 mol, see Example 2) was added to the TDMAZr solution. The mixture was stirred for overnight at room temperature. After the reaction, the solution was removed under vacuum condition. The crude was yellow liquid. The material was then purified by distillation up to 115° C.@40 mTorr to give 27.91 g (84%) of yellow liquid. The product was characterized ¹H NMR: (ppm) in C₆D₆: [5.94˜5.74(m, 3H)], [2.96(s) (18H)], [2.48(q), 2.40(q) (2H)], [2.09 (s), 2.00(s) (3H)], [1.14(t), 1.10 (t) (3H)]. The purified product left a 2.2% residual mass during open-cup TGA analysis measured at a temperature rising rate of 10° C./min in an atmosphere which flows nitrogen at 200 mL/min. These results are shown in FIG. 4, which is a TGA graph illustrating the percentage of weight upon temperature increase. Onset temperature of decomposition (325° C.) of the product was measured by DSC, which are shown in FIG. 5.

### Example 6: ALD Using Hf(Me(nPr)Cp)(NMe₂)₃

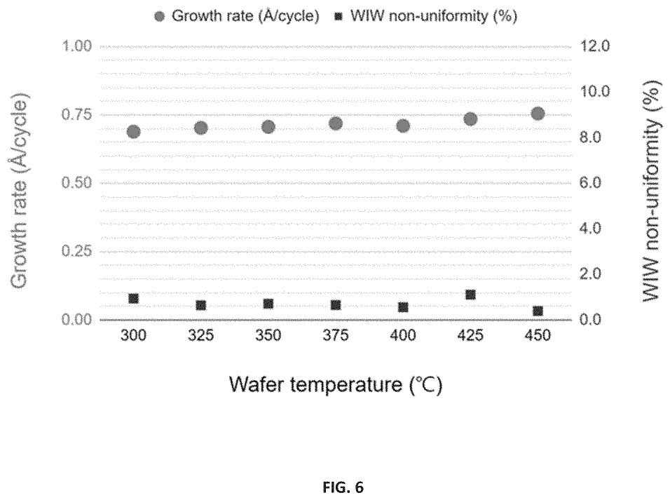

Thermal ALD using precursor Hf(Me(nPr)Cp)(NMe₂)₃ and co-reactant O₃ was performed on Si bare wafer. The canister containing Hf(Me(nPr)Cp)(NMe₂)₃ was maintained at 85° C. (VP˜0.4 Torr). The ALD chamber pressure was set at 1 Torr. The ALD process temperature was set at temperatures ranging from approximately 250° C. to approximately 425° C. These results are shown in FIG. 6 which is a graph showing the formed HfO₂ film growth rate as a function of the chamber temperature using Hf(Me(nPr)Cp)(NMe₂)₃. Thermal ALD deposition occurred at temperatures ranging from approximately 300° C. to approximately 400° C., where non-uniformity is low.

### Example 7: ALD Using Zr(Me(Et)Cp)(NMe₂)₃

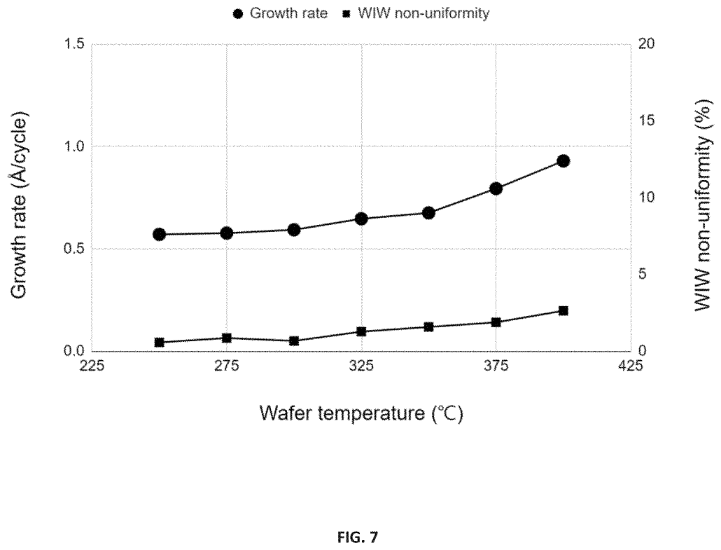

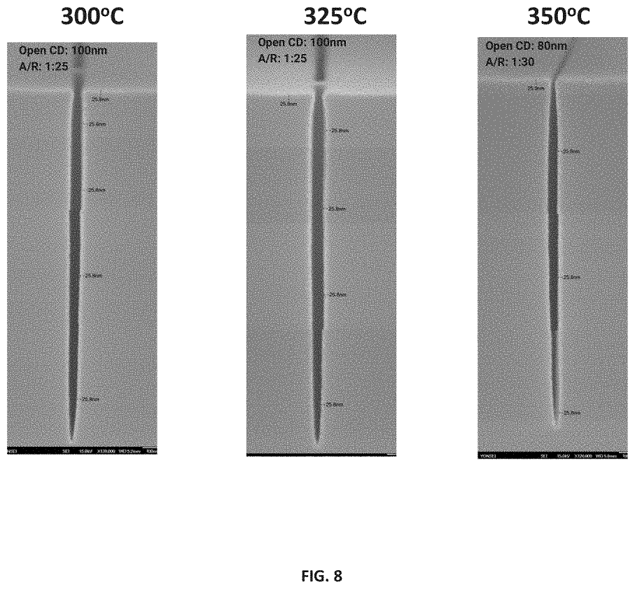

Thermal ALD using precursor Zr(Me(Et)Cp)(NMe₂)₃ and co-reactant O₃ was performed on Si bare wafer. The canister containing Zr(Me(Et)Cp)(NMe₂)₃ was maintained at 85° C. (VP˜0.4 Torr). The ALD chamber pressure was set at 1 Torr. The ALD process temperature was set at temperatures ranging from approximately 250° C. to approximately 425° C. These results are shown in FIG. 7 which is a graph showing the formed ZrO2 film growth rate as a function of the chamber temperature using Zr(Me(Et)Cp)(NMe₂)₃. Thermal ALD deposition occurred at temperatures ranging from approximately 300° C. to approximately 400° C., where non-uniformity is low. FIG. 3 shows the vapor pressure of Zr(Me(Et)Cp)(NMe₂)₃ at various temperatures. FIG. 8 is a photograph of SEM of NrO₂ films deposited in a patterned structure. The step coverage is 100% at aspect ratio 30:1.

It will be understood that many additional changes in the details, materials, steps, and arrangement of parts, which have been herein described and illustrated in order to explain the nature of the invention, may be made by those skilled in the art within the principle and scope of the invention as expressed in the appended claims. Thus, the present invention is not intended to be limited to the specific embodiments in the examples given above and/or the attached drawings.

While embodiments of this invention have been shown and described, modifications thereof may be made by one skilled in the art without departing from the spirit or teaching of this invention. The embodiments described herein are exemplary only and not limiting. Many variations and modifications of the composition and method are possible and within the scope of the invention. Accordingly, the scope of protection is not limited to the embodiments described herein, but is only limited by the claims which follow, the scope of which shall include all equivalents of the subject matter of the claims.

We claim:

1. A method for forming a Group IV transition metal containing film, the method comprising the steps of:
a) exposing a substrate to a vapor of a Group IV transition metal containing film forming composition;
b) exposing the substrate to a co-reactant; and
c) repeating the steps of a) and b) until a desired thickness of the Group IV transition metal containing film is deposited on the substrate using a vapor deposition process,
wherein the Group IV transition metal containing film forming composition comprises a precursor having the formula:
M(R¹R²Cp)ₐ(L¹)_{b}
wherein, M is a Group IV transition metal selected from Zr, Hf or Ti;
Cp is cyclopentadiene;
R¹ and R² each are independently selected from the group consisting of H and —(CX₂)ₚCY₃, wherein X is independently H or F, Y is independently H or F, p is 0 to 10;
L¹ is −1 anionic ligand selected from halides, amidinate group, beta diketonate, non-fluorinated dienyl group, alkyl group, —OR³, —NR³R⁴, wherein R³ and R⁴ each are independently selected from the group consisting of H and —(CX′₂)_{q}CY′₃, wherein X′ is independently H or F, Y′ is independently H or F, q is 0 to 10; and
a+b=4.

2. The method of claim 1, further comprising the steps of introducing an inert gas purge following the steps a) and b), respectively, to separate each exposure, wherein the inert gas purge uses an inert gas selected from N₂, Ar, Kr, or Xe.

3. The method of claim 1, further comprising the step of plasma treating the co-reactant.

4. The method of claim 1, wherein the co-reactant is selected from O₂, O₃, H₂O, H₂O₂, NO, N₂O, NO₂, oxygen radicals thereof or mixtures thereof, or H₂, H₂CO, N₂H₄, NH₃, an amine, a hydrazine N(SiH₃)₃, radicals thereof or mixtures thereof.

5. The method of claim 1, wherein the co-reactant is NH₃ or O₃.

6. The method of claim 1, wherein the precursor is Hf(Me(Me)Cp)(NMe₂)₃.

7. The method of claim 1, wherein the precursor is Hf(Me(Et)Cp)(NMe₂)₃.

8. The method of claim 1, wherein the precursor is Hf(Me(nPr)Cp)(NMe₂)₃.

9. The method of claim 1, wherein the precursor is Hf(Me(nBu)Cp)(NMe₂)₃.

10. The method of claim 1, wherein the precursor is Zr(Me(Et)Cp)(NMe₂)₃.

11. The method of claim 1, wherein the Group IV transition metal containing film is an oxide film or nitride film.

12. The method of claim 1, wherein the vapor deposition process is an ALD process or a CVD process.

13. The method of claim 1, wherein the vapor deposition process is a PEALD process or a spatial ALD process.

14. The method of claim 1, wherein a deposition temperature ranges from approximately 100° C. and approximately 600° C.

15. The method of claim 1, wherein the substrate is a powder that comprises one or more of NMC (Lithium Nickel Manganese Cobalt Oxide), LCO (Lithium Cobalt Oxide), LFP (Lithium Iron Phosphate), and other battery cathode materials.

16. A Group IV transition metal containing film forming composition for a vapor deposition process comprising a precursor having the formula:
M(R¹R²Cp)ₐ(L¹)_{b}
wherein, M is a Group IV transition metal selected from Zr, Hf or Ti;
Cp is cyclopentadiene;
R¹ and R² each are independently selected from the group consisting of H and —(CX₂)ₚCY₃, wherein X is independently H or F, Y is independently H or F, p is 0 to 10,
L¹ is −1 anionic ligand selected from halides, amidinate group, beta diketonate, non-fluorinated dienyl group, alkyl group, —OR³, —NR³R⁴, wherein R³ and R⁴ each are independently selected from the group consisting of H and —(CX′₂)_{q}CY′₃, wherein X′ is independently H or F, Y′ is independently H or F, q is 0 to 10; and
a+b=4.

17. The Group IV transition metal containing film forming composition of claim 16, wherein each R¹, R², R³, and R⁴ is independently H, Me, Et, nPr, iPr, tBu, sBu, iBu, nBu, or tAmyl.

18. The Group IV transition metal containing film forming composition of claim 16, wherein the precursor is Hf(Me(Me)Cp)(NMe₂)₃, Hf(Me(Et)Cp)(NMe₂)₃, Hf(Me(nPr)Cp)(NMe₂)₃, Hf(Me(nBu)Cp)(NMe₂)₃ or Zr(Me(Et)Cp)(NMe₂)₃.

19. A method of forming a ZrO2 film or coating by an ALD process on a substrate, the method comprising the steps of:
a) exposing the substrate to a vapor of Zr(Me(Et)Cp)(NMe₂)₃;
b) exposing the substrate to an oxidizer; and
e) repeating the steps of a) and b) until a desired thickness of the ZrO₂ film is deposited on the substrate using the ALD process.

20. The method of claim 19, further comprising the steps of introducing an inert gas purge following the steps a) and b), respectively, to separate each exposure.
